(19) United States
(12) Patent Application Publication
(10) Pub. No.: US 2006/0138518 A1
(43) Pub. Date: Jun. 29, 2006

(54) Semiconductor device with silicon-germanium gate electrode and method for manufacturing thereof

(75) Inventors: Akiyoshi Mutou, Nara (JP); Hiroshi Ohji, Kyoto (JP)

Correspondence Address: LEYDIG VOIT & MAYER, LTD, 700 THIRTEENTH ST. NW, SUITE 300, WASHINGTON, DC, 20005-3960, US

(73) Assignee: Sharp Kabushiki Kaisha, Osaka-shi (JP)

(21) Appl. No.: 11/360,398

(22) Filed: Feb. 24, 2006

Related U.S. Application Data
(62) Division of application No. 10/925,990, filed on Aug. 26, 2004.

(30) Foreign Application Priority Data
Aug. 29, 2003 (JP) 2003-307148

(51) Int. Cl. H01L 29/94

(52) U.S. Cl. 257/310

(57) ABSTRACT

A semiconductor includes a gate electrode having a SiGe film on a a gate dielectric film that is on a silicon substrate. The gate dielectric film includes an underlying interfacial layer on the substrate and a high-k dielectric film having higher dielectric constant than the underlying interfacial layer. The gate electrode includes a seed Si film on the high-k dielectric film and a SiGe film on the seed Si film. The seed Si film has a thickness of 0.1 nm or more and smaller than 5 nm.

### 1. FIELD OF THE INVENTION

The present invention relates to a semiconductor device and to a method for manufacturing thereof. More specifically the present invention relates to a gate electrode including a thin SiGe film and to a method for manufacturing thereof.

### 2. DESCRIPTION OF THE BACKGROUND ART

In recent years, MOSFET (metal oxide semiconductor field effect transistor) as a semiconductor device has been extremely miniaturized and highly integrated. Concurrent to this trend, the thickness of a gate dielectric film has been reduced from the point of view of securing the driving current and saving power consumption. For meet the demands of scaling lows, the thickness of a silicon oxide film (SiO₂ film) which has been used as a gate dielectric film, need to be 2 nm or less.

However, in case of that the thin SiO₂ film is used as the gate dielectric film, gate current leakage owing to tunnel current leakage cannot be ignore as compared with source-drain current, thereby arising problems in the highly integration and power saving of MOSFETs.

In order to cope with such problems, there has been proposed to use high-dielectric-constant film (also called “high-k film”) with higher dielectric constant than that of SiO₂ film as the gate dielectric film. As materials of the high-k film, for example, a metal oxide such as HfO₂, ZrO₂ and Al₂O₃; a metal silicate such as HfSiOₓ and ZrSiOₓ; a metal aluminate such as HfAlOₓ and ZrAlOₓ; and an oxide of Lanthanide such as La₂O₃ and Y₂O₃ can be used. The high-k film containing hafnium such as hafnium oxide film (HfO₂ film), hafnium aluminate film (HfAlOₓ film) and hafnium silicate film (HfSiOₓ film), and aluminium oxide film (Al₂O₃ film), and there nitride film especially have good thermal stability, so it is easy to apply these films to LSI manufacturing processes.

These high-k films have dielectric constant of 6 or more, and have higher dielectric constant than that of SiO₂ film. Physical thickness of the gate dielectric film can be thicker with thin electrical thickness (EOT: equivalent oxide thickness) of gate dielectric film maintained. Therefore, the gate current leakage owing to tunnel current leakage can be reduced.

Also, in order to thin the EOT of gate dielectric films, there has been proposed to reduce the value of parasitic capacitance resulted from the depletion generated in a gate electrode. For example, there is one way that silicon germanium (hereafter referred to “SiGe”) is used for the gate electrode. The use of a SiGe film in the gate electrode of an MOSFET can improve the activation rate of conductive impurities (e.g., boron) in the gate electrode, inhibit the depletion of the gate electrode, thus reducing the parastic capacitance. This allows the use of a gate dielectric film with a decreased thickness, correspondingly reducing the parasitic capacitance.

Also, in order to lower the resistance of a gate electrode with SiGe film, there is a case that a silicide film is formed on the gate electrode using saliside process. However, in this case, there is a problem of the occurrence of silicide cohesion and defective resistance caused by Ge in the SiGe film. In order to solve this problem, there has been proposed to form a thick cap Si film on the SiGe film, and to adjust the Ge concentration in the surface of the cap Si film to 2% of less (e.g., refer to Japanese Patent Laid-Open No. 2002-261274 (Page 5, FIG. 1)).

Also, there are problems that a surface of a SiGe film is roughened during formation of the SiGe film and it is difficult of patterning a gate electrode using dry etching. In order to reduce surface roughness of the SiGe film, there has been proposed to form an amorphous Si film as a seed Si film on SiO₂ film serving as a gate dielectric film and to form SiGe film on the seed Si film (refer to the Japanese Patent Laid-Open No. 2002-261274).

Also, there has been proposed that polycrystalline SiGe film is formed after formation of Si fines on SiO₂ film, and thereby the equation of Ge content in the SiGe film at boundary between the SiO2 and SiGe film, and thereby reducing lattice strain in grains of the SiGe film and stress of the SiGe film, and reliability of the gate electrode can be improved (e.g., refer to the Japanese Patent Laid-Open No. 2003-31806).

However, according to investigation by the present inventors, when a cap Si film is formed on the SiGe film, there are problems such that the surface roughness of the SiGe film increases; a discontinuous SiGe film is formed; and voids are formed in SiGe film due to grain growth.

Furthermore, according to investigation by the present inventors, in the case of using the high-k film as the gate dielectric film, the way of arising defectives of the SiGe film is different from the case of using silicon oxide film (SiO₂ film) or silicon oxynitride film (SiON film). The examples of the defectives of the SiGe film show as follows.

FIGS. 10A and 10B are SEM photographs showing a form of the SiGe film when the laminated films having the SiGe film and the cap Si film on the high-k film. Specifically, FIG. 10A is a SEM photograph showing the cross section of the SiGe film when the hafnium aluminate film (HfAlOₓ film) having a Hf content of 23% is used as the high-k film. FIG. 10B is a SEM photograph showing the cross section of the SiGe film when the hafnium silicate film (HfSiOₓ film) having a Hf content of 60% is used as the high-k film. FIG. 11 is a SEM photograph showing a form of the SiGe film when the laminated films having the SiGe film and the cap Si film on the aluminum oxide film (Al₂O₃ film) serving as the high-k film through the seed Si film of a thickness of 5 nm or more (5 nm in FIG. 11).

As FIGS. 10A and 10B show, in the case that the SiGe film is directly formed on the high-k film, there are problems that the SiGe film has an island-form, and the SiGe film becomes discontinuous. Furthermore, as FIGS. 10A and 10B show, there is problem that the surface roughness of the SiGe film becomes worse significantly.

As FIG. 11 show, in the case that the seed Si film of a thickness of 5 nm or more is disposed between the high-k film and the SiGe film, there is a problem that voids (refer to circled portions in FIG. 11) generate in the SiGe film.

### SUMMARY OF THE INVENTION

The present invention has been conceived to solve the previously-mentioned problems and a general object of the present invention is to provide novel and useful semiconductor device and is to provide novel and useful method for manufacturing a semiconductor device.

A more specific object of the present invention is to form a void-free SiGe film having good surface flatness on a high-k film. Another specific object of the present invention is to form high-quality continuous films including the SiGe film and the cap Si film on a high-k film.

The above object of the present invention is attained by a following semiconductor device and a following method for manufacturing a semiconductor device.

According to one aspect of the present invention, the semiconductor device comprises a gate dielectric film formed on a substrate, and a gate electrode formed on the gate dielectric film. The gate dielectric film includes: an underlying interfacial layer formed on the substrate; and a high-k dielectric film having higher dielectric constant than the underlying interfacial layer. The gate electrode formed includes: a seed Si film formed on the high-k dielectric film; and a SiGe film formed on the seed Si film.

According to another aspect of the present invention, in the method for manufacturing a semiconductor device, a high-k dielectric film is first formed as a gate dielectric film on a substrate. A seed Si film is formed on the high-k dielectric film. A SiGe film is formed on the seed Si film. The SiGe film and the seed Si film are patterned to form a gate electrode, and the high-k dielectric film is patterned. Impurities diffusion regions are formed in upper layer of the substrate through ion implantation using the gate electrode as a mask.

Other objects and further features of the present invention will be apparent from the following detailed description when read in conjunction with the accompanying drawings.

### BRIEF DESCRIPTION OF THE DRAWINGS

FIG. 1 is a schematic cross-sectional view for illustrating a semiconductor device according to a first embodiment of the present invention;

FIGS. 2A to 2E are process sectional views for illustrating a method for manufacturing the semiconductor device shown in FIG. 1;

FIG. 3A is a graph for showing relationship between a thickness of the seed Si film and an electrical thickness (EOT) obtained from capacitance characteristic;

FIG. 3B is a graph for showing relationship between a thickness of the seed Si film and a depletion ratio of the SiGe film obtained from capacitance characteristic;

FIG. 4A is a SEM photograph showing a form of the SiGe film when the hafnium aluminate film (HfAlOₓ film) having a Hf content of 23% is used as the high-k dielectric film;

FIG. 4B is a SEM photograph showing a form of the SiGe film when the hafnium silicate film (HfSiOₓ film) having a Hf content of 60% is used as the high-k dielectric film;

FIG. 4C is a SEM photograph showing a form of the SiGe film when the aluminum oxide film (Al₂O₃ film) is used as the high-k dielectric film;

FIG. 5 is a schematic cross-sectional view for illustrating a semiconductor device according to a second embodiment of the present invention;

FIGS. 6A to 6D are process sectional views for illustrating a method for manufacturing the semiconductor device shown in FIG. 5;

FIG. 7 is a schematic cross-sectional view for illustrating a semiconductor device according to a third embodiment of the present invention;

FIGS. 8A to 9B are process sectional views for illustrating a method for manufacturing the semiconductor device shown in FIG. 7;

FIGS. 10A and 10B are SEM photographs showing a form of the SiGe film when the laminated films having the SiGe film and the cap Si film on the high-k film; and

FIG. 11 is a SEM photograph showing a form of the SiGe film when the laminated films having the SiGe film and the cap Si film on the aluminium oxide film (Al₂O₃ film) serving as the high-k film through the seed Si film of a thickness of 5 nm or more.

### DETAILED DESCRIPTION OF THE PREFERRED EMBODIMENTS

In the following, principles and embodiments of the present invention will be described with reference to the accompanying drawings. The members and steps that are common to some of the drawings are given the same reference numerals and redundant descriptions therefore may be omitted.

### First Embodiment

First, the structure of a semiconductor device according to a first embodiment of the present invention will be described.

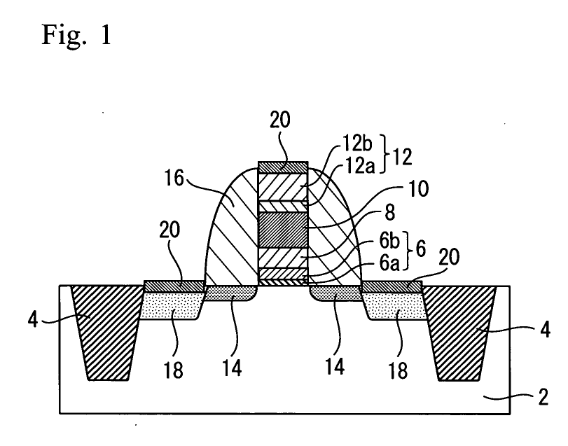

FIG. 1 is a schematic cross-sectional view for illustrating a semiconductor device according to a first embodiment of the present invention.

As FIG. 1 shows, a silicon substrate serving as the substrate 2 has element regions on which semiconductor elements such as transistors are formed, and isolation regions for isolating the element regions, in which field insulating films (also referred to as “element-isolating insulating films”) 4 are formed. Well regions (not shown) are formed in the element regions of the substrate 2.

On the substrate 2 in the element regions, a gate dielectric film 6 is formed. The gate dielectric film 6 is laminated film includes: an underlying interfacial layer 6a formed on the silicon substrate 2; and high-k dielectric film 6b formed on the underlying interfacial layer 6a and having higher dielectric constant than the underlying interfacial layer 6a.

As the underlying interfacial layer 6a, for example, a SiO₂ film, a Si₃N₄ film, or a SiON film (hereafter collectively referred to as “SiO₂ film or the like”) can be used. The thickness of the underlying interfacial layer 6a is, for example, 0.5 nm to 1 nm. The underlying interfacial layer 6a is acted to inhibit interfacial reaction between the silicon substrate 2 and the high-k dielectric film 6b.

As the high-k dielectric film 6b, for example, a hafnium aluminate film (HfAlOₓ film) having Hf content of below 50%, a hafnium silicate film (HfSiOₓ film), and an aluminium oxide film (Al₂O₃ film), and there nitride film can be used. The high-k dielectric film 6b has dielectric constant of 6 or more. The thickness of the high-k dielectric film 6b is, for example, 2 nm to 3 nm.

On the gate dielectric film 6 is formed a gate electrode composed of the laminate of a seed Si film 8, a SiGe film 10, a lower cap Si film 12a, an upper cap Si film 12b and a silicide layer 20.

Specifically, on the high-k dielectric film 6b is formed an amorphous Si film serving as the seed Si film 8. The thickness of the seed Si film 8 is preferably 0.1 nm or more and smaller than 5 nm (described later). On the seed Si film 8 is formed the SiGe film 10 serving a lower electrode film. The thickness of the SiGe film 10 is preferably 50 nm or below. The SiGe film 10 is represented by a composition formula of Si₍₁₋ₓ₎Geₓ, and the Ge content X is preferably 0.15 or more and smaller than 0.4 (15% or more and smaller than 40%), and more preferably about 0.3 (30%) (described later). The SiGe film 10 is preferably grown at a growth temperature of 450° C. or above and below 500° C., and more preferably 475° C. (described later).

On the SiGe film 10 is formed the cap Si film 12. The cap Si film 12 includes: the lower cap Si film 12a grown at the same temperature as the SiGe film 10 and having the same film form as the SiGe film 10; and the upper cap Si film 12b grown at higher temperature than the lower cap Si film 12a and having different film form from the lower cap Si film 12a. The thickness of the lower cap Si film 12a is preferably 0.1 nm or more and smaller than 5 nm. The thickness of the upper cap Si film 12b is preferably It is preferable that the thin SiGe film 10 and the lower cap Si film 12a are continuously formed using the same apparatus at the same temperature.

Sidewalls 16 are formed on the sides of the gate dielectric film 6, the seed Si film 8, the SiGe film 10 and the cap film 12.

Extension regions 14 sandwiching a channel region (not shown) underneath the gate electrode are formed in the upper layer of the silicon substrate 2. Source-drain regions 18 connecting to the extension regions 14 are formed in the upper layer of the silicon substrate 2.

Nickel silicide layers serving as silicide layers 20 are formed in upper layers of the upper cap Si film 12b and the source-drain regions 18. That is to say, MOSFET of the first embodiment has salicide structure.

Next, a method for manufacturing the above-described semiconductor device will be described.

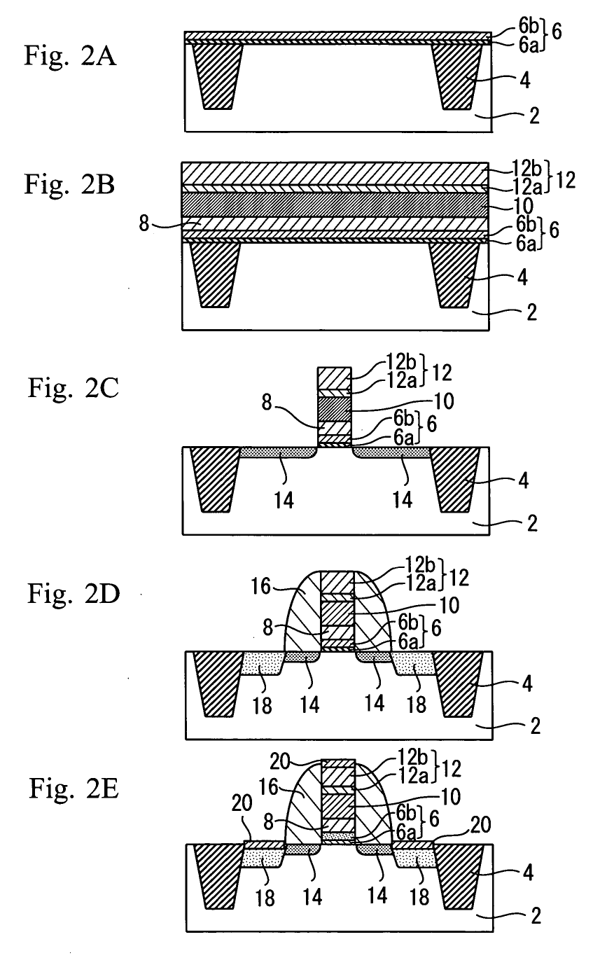

FIGS. 2A to 2E are process sectional views for illustrating a method for manufacturing the semiconductor device shown in FIG. 1.

First, as FIG. 2A shows, field insulating films 4 are formed in the isolation regions of a silicon substrate 2 using STI (shallow trench isolation) method. Then, the ions of a conductive impurity are implanted into the element regions (not shown) of the silicon substrate 2, and annealing is performed to form well regions.

Next, after a predetermined pretreatment (e.g., the removal of natural oxide films) has been performed, a SiO₂ film or the like (described above) with a thickness of, for example, 0.5 nm to 1 nm is formed as an underlying interfacial layer 6a on the silicon substrate 2 using a method such as thermal oxidation (or thermal nitriding or thermal oxynitriding) or plasma oxidation (or plasma nitriding or plasma oxynitriding).

Next, a high-k dielectric film 6b having higher dielectric constant than the underlying interfacial layer 6a is formed on the underlying interfacial layer 6a using an ALD (atomic layer deposition) method or an MOCVD (metal organic chemical vapor deposition) method. For example, when the HfAlOx film is formed as the high-k dielectric film 6b using ALD method, the following process conditions can be used, raw material: HfCl₄ and TMA (trimethyl-aluminum); oxidizer: H₂O or O₃; and substrate temperature: 300° C.

Thus, the gate dielectric film 6 laminated the underlying interfacial layer 6a and the high-k dielectric film 6b is formed in the silicon substrate 2.

After formation of the high-k dielectric film 6b, thermal process (annealing) is preferably performed in atmosphere including a little oxygen. For example, when the HfAlOx film is formed as the high-k dielectric film 6b, thermal process with a temperature of about 1000° C. and a process time of a few minutes can be performed using a lamp-type RTA (rapid thermal annealer) preferably. Thus, defects of oxygen in the high-k dielectric film 6b can be improved, and concentration of impurity in the high-k can be decreased.

Furthermore, a silicon nitride (SiN film) or an aluminum nitride (AlN film) with a thickness of 0.1 nm to 1 nm can be formed on the high-k dielectric film 6b. That is to say, thin SiN film or thin AlN film can be disposed between high-k dielectric film 6b and the seed Si film 8. In this case, diffusion of dopant of the gate electrode to the high-k dielectric film can be reduced. Therefore, gate current leakage can be reduced, and reliability of a semiconductor element can be improved.

Next, as FIG. 2B shows, an amorphous Si film serving as a seed Si film 8 is formed on the high-k dielectric film 6b using a LPCVD (low pressure chemical vapor deposition) method. In order to attain the maximum improvement of electrical characteristic of the SiGe film 10, a thickness of the seed Si film 8 is preferably 0.1 nm or more and smaller than 5 nm, and more preferably 1 nm to 3 nm. For the formation of the seed Si film 8, for example, a batch-type vertical LPCVD apparatus can be used. The conditions for forming the seed Si film 8 in a LPCVD apparatus are, for example, a SiH₄ flow rate of 1 slm, a growth temperature of 475° C., and a growth pressure of 100 Pa.

The present inventors investigate electrical characteristic of a transistor when a laminated film composed of the SiGe film and the cap Si film is formed on the high-k dielectric film through the seed Si film. In this investigation, the HfAlOₓ film having Hf content of 23% is used as the high-k film.

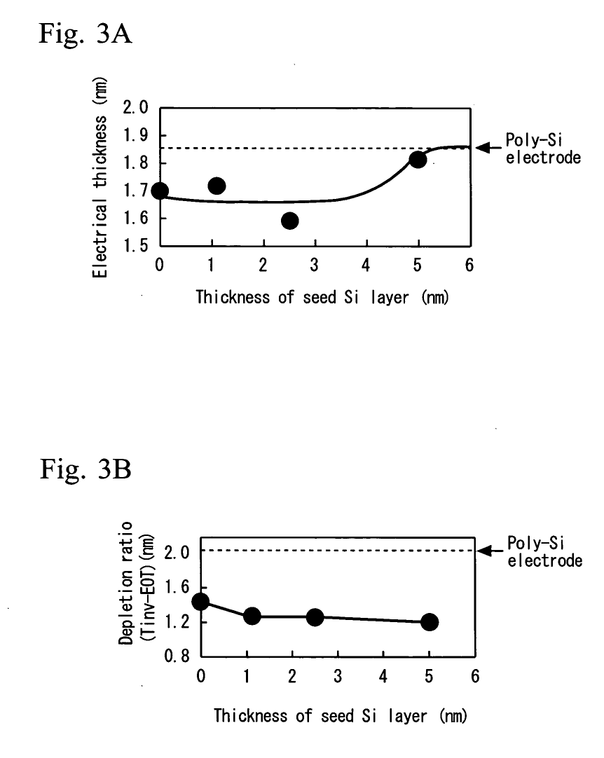

FIGS. 3A and 3B are graphs for showing electrical characteristic of a transistor when a laminated film composed of the SiGe film and the cap Si film is formed on the high-k dielectric film through the seed Si film. Specifically, FIG. 3A is a graph for showing relationship between a thickness of the seed Si film and an electrical thickness (EOT) obtained from capacitance characteristic (C-V characteristic) FIG. 3B is a graph for showing relationship between a thickness of the seed Si film and a depletion ratio of the SiGe film obtained from capacitance characteristic (C-V characteristic).

As FIG. 3A shows, in the case that the thickness of the seed Si film is thin, a value of electrical thickness (EOT) is low and favorable. A laminated gate electrode composed of the seed Si film with the thickness of smaller than 5 nm and SiGe film, the electrical thickness (EOT) can be reduced as compared with conventional case of polycrystalline silicon (Poly-Si) gate electrode. The reason for reduction of EOT is that solid-phase reaction at interface between the gate electrode and the high-k dielectric film is restrained by using the SiGe film. In the case that the thickness of the seed Si film is 5 nm and more thick, above-mentioned reduction of EOT cannot be attained since Ge content is low at the interface and it is insufficient for restraining the solid-phase reaction. Therefore, the thickness of the seed Si film is preferably smaller than 5 nm.

In FIG. 3B, as index of depletion ratio, the difference (Tinv−EOT) between reversal capacitance thickness (Tinv) obtained from C-V characteristic and electrical thickness (EOT) is used. The smaller the difference is, the more depletion of the gate electrode is restrained, and the better electrical characteristic of the transistor becomes. As FIG. 3B shows, regardless of thickness of the seed Si film, depletion of the gate electrode can be restrained by using SiGe gate electrode as compared with conventional case of polycrystalline silicon (Poly-Si) gate electrode. Therefore, the thickness of the seed Si film is preferably 0.1 nm or more.

According to the above-mentioned result of investigation shown in FIGS. 3A and 3B, a thickness of the seed Si film 8 is preferably 0.1 nm or more and smaller than 5 nm.

Next, as FIG. 2B shows, a SiGe film 10 is formed on the seed Si film 8 using the LPCVD apparatus. Specifically, the seed Si film 8 and the SiGe film 10 are continuously formed using the above-described LPCVD apparatus.

Here, the Ge content Y in the thin SiGe film 10 represented by the composition formula, Si_{(1-y)}Ge_{y}, is preferably 0.15 or more and smaller than 0.4 (15% or more and smaller than 40%), and most preferably 0.3 (30%). Improving effect of electrical characteristic of PMOS is not satisfactory when the Ge content is less than 0.15 (15%), and the improving effect is saturated when the Ge content is 0.3 (30%) or more. On the other hand, electrical characteristic of PMOS becomes worse when the Ge content is 0.4 (40%) and more.

The growth temperature of the thin SiGe film 10 is preferably 450° C. or above and less than 500° C., and most preferably 475° C. Surface roughness of the SiGe film increases when the growth temperature is 500° C. or more. On the other hand, when the growth temperature is below 450° C., the growth rate of the SiGe film is lowered, and therefore the throughput is lowered.

The conditions for forming SiGe film in the batch-type vertical LPCVD apparatus are, for example, a SiH₄ flow rate of 0.6 slm, a H₂-diluted 10% GeH₄ flow rate of 0.58 slm, a growth temperature of 475° C., and a growth pressure of 10 Pa. The SiGe film having a Ge content of 0.3 (30%) with a thickness of about 40 nm can be formed under these conditions, and the SiGe film have a favorable surface flatness and a favorable uniformity of the film thickness on the surface.

Next, a cap Si film 12 laminated a lower cap Si film 12a and an upper cap Si film 12b is formed on the thin SiGe film 10 using the above-described LPCVD apparatus. Here, the SiGe film 10 and the lower cap Si film 12a are continuously formed at the same temperature, thereby forming the lower cap Si film 12a having the same form as the SiGe film 10. Thereafter, the upper cap Si film 12b is formed at the higher temperature than the lower cap Si film 12a, thereby forming the upper cap Si film 12b having different form from the lower cap Si film 12a.

The lower cap Si film 12a with a thickness of about 5 nm can be formed using a batch-type vertical LPCVD apparatus under the conditions: a SiH₄ flow rate of 1 slm; a temperature of 475° C.; and a pressure of 100 Pa. Furthermore, the upper cap Si film 12b with a thickness of about 110 nm can be formed using the batch-type vertical LPCVD apparatus under the conditions: a SiH₄ flow rate of 0.6 slm; a temperature of 620° C.; and a pressure of 20 Pa.

Since the lower cap Si film 12a having the same form as the SiGe film 10 is formed, a change in the form of the SiGe film 10 can be restrained during formation of the upper cap Si film 12b, and film deficient such as voids can be restrained in the SiGe film 10. The reason is that the lower cap Si film 12a lowers the surface energy the SiGe film 10 and thermally stabilizes the thin SiGe film 10. Further, since the lower cap Si film 12a is formed on the SiGe film 10, a silicide layer 20 (described later) can be formed stably.

If the silicide layer 20 (described later) is not formed, the formation of the upper cap Si film 12b can be omitted. In this case, since the SiGe film 10 is formed on the high-k dielectric film 6b through the seed Si film 8, a high-quality SiGe film can be formed above the high-k dielectric film 6b.

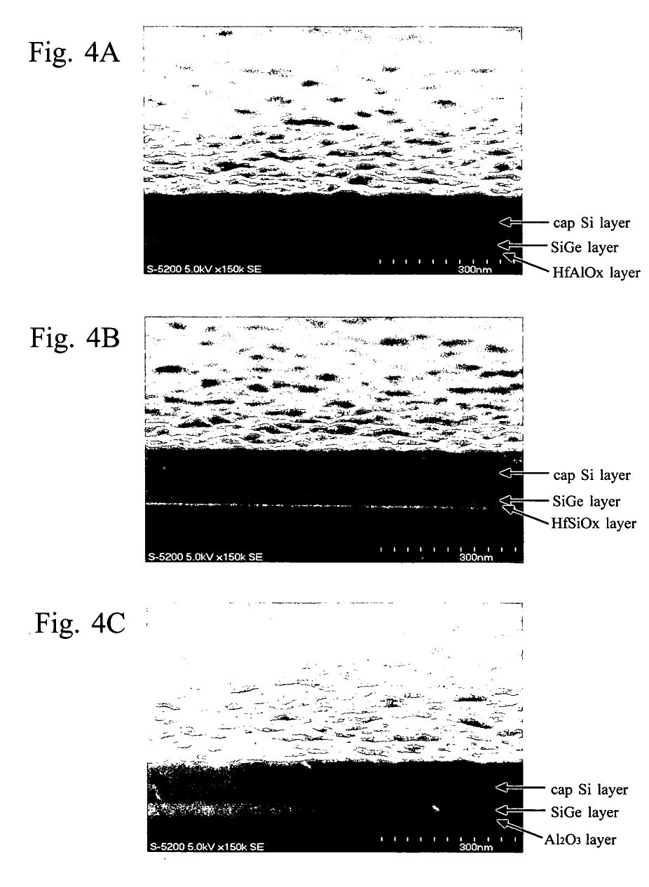

FIGS. 4A to 4C are SEM photographs showing a form of the SiGe film when the laminated films composed of the SiGe film and the cap Si film on the high-k film through the seed Si film. Specifically, FIG. 4A is a SEM photograph showing a form of the SiGe film when the hafnium aluminate film (HfAlOₓ film) having a Hf content of 23% is used as the high-k dielectric film. FIG. 4B is a SEM photograph showing a form of the SiGe film when the hafnium silicate film (HfSioₓ film) having a Hf content of 60% is used as the high-k dielectric film. FIG. 4C is a SEM photograph showing a form of the SiGe film when the aluminum oxide film (Al₂O₃ film) is used as the high-k dielectric film. Here, a thickness of the seed Si film is 1 nm.

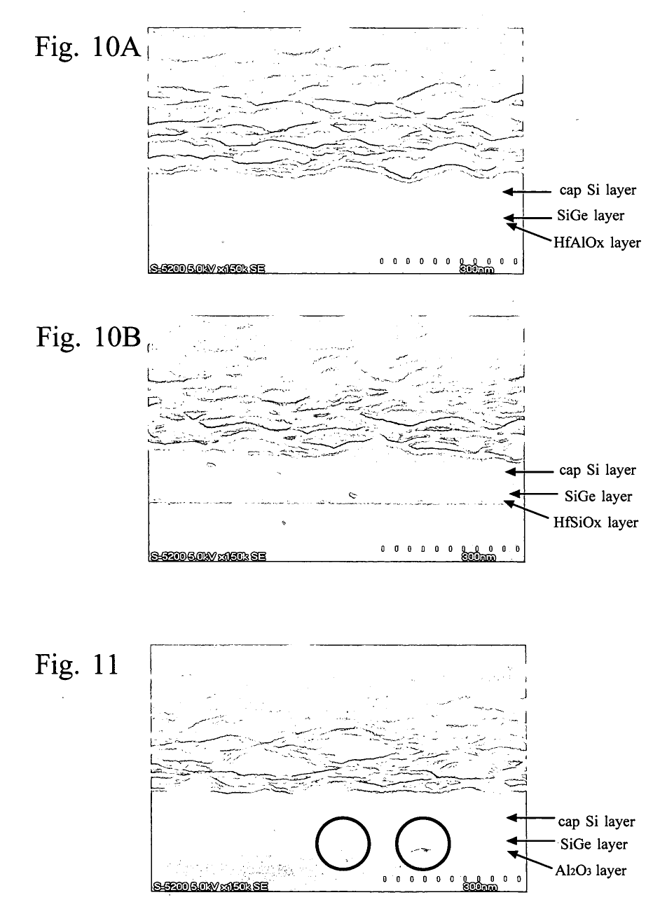

As FIGS. 4A to 4C show, in the cases of all high-k dielectric film, since the SiGe film is formed through the seed Si film, an island-form which is seen when without the seed Si film (refer to FIGS. 10A and 10B), is not seen in the SiGe film, and the SiGe film having a good-form can be formed. Further, as FIGS. 4A to 4C show, voids (refer to FIG. 11) are not seen in the SiGe film. The present inventor confirm that the island-form and the voids are not seen in the SiGe film when the thickness of the seed Si film is 0.1 nm or more and smaller than 5 nm. This shows a favorable thickness range of the seed Si film to the gate dielectric film including the high-k dielectric film.

Next, conductive impurities are introduced in the cap Si film 12 and the SiGe film 10. Thereafter, the cap Si film 12, the SiGe film 10, the seed Si film 8, and the gate dielectric film 6 are sequentially patterned using lithography technique and etching technique well known in the art. Thereby, as FIG. 2C shows, the gate electrode of the MOSFET is formed.

Conductive impurities are implanted in the silicon substrate 2 using a patterned gate electrode and gate dielectric film 6 as a mask, and thermal process is performed. Thereby, extension regions 14 are formed in the upper portion of the substrate 2.

Next, an insulating film such as Si₃N₄ or SiO₂ is formed over the entire of the silicon substrate 2, and the insulating film is etched using an anisotropic dry etching method. Thus, as FIG. 2D shows, sidewall-spacers 16 are formed on the sides of the gate electrode and the gate dielectric film 6.

Conductive impurities are implanted in the silicon substrate 2 using gate electrode, gate dielectric film 6 and sidewall-spacers 16 as a mask, and thermal process is performed. Thereby, source-drain regions 18 connected to the extension regions 14 are formed in the upper portion of the substrate 2.

Next, as FIG. 2E shows, silicide layers 20 are formed in upper portions of the upper cap Si film 12b and source-drain regions 18 using self-aligned silicide formation technique called “salicide technique”.

Specifically, after a predetermined pretreatment has been performed using diluted HF solution, a Ni film with thickness of about 10 nm is formed over the entire of the silicon substrate 2, and a TiN film with thickness of about 10 nm is formed on the Ni film. Thereafter, a heat treatment with a temperature of about 500° C. and time of about 30 seconds is performed. Thus, Ni film is reacted with the upper cap Si film 12b and the source-drain regions 18, and no-reacted metal is removed. Thereby, NiSi layers serving as silicide layers 20 are formed.

In the first embodiment, as described above, the SiGe film 10 is formed above the high-k dielectric film 6 such as HfAlOx film having Hf content of smaller than 50% through the seed Si film 8 with a thickness of 0.1 nm or more and smaller than 5 nm. Therefore, a void-free SiGe film 10 having high-flatness can be formed above the high-k dielectric film 6b. That is to say, a continuous SiGe film having no voids can be formed with high-flatness of the SiGe film 10 maintained.

Also, after formation of the SiGe film 10, the lower cap Si film 12a is formed at the same growth temperature as the SiGe film 10. Thus, a continuous film structure composed of the SiGe film 10 and the lower cap Si film 10a can be formed.

A uniformity of Ge content in the interface between the gate electrode and the gate dielectric film can be improved, and dispersion of threshold voltage of the transistor due to local dispersion of Ge content in the interface can be restrained. Dispersion of semiconductor elements can be restrained, and high-performance transistors can be manufactured with the high productivity.

Also, since the SiGe film is used as the gate electrode, depletion of the gate electrode can be restrained, and it becomes possible to make the thickness of the gate dielectric film thin. Therefore, high-performance transistor can be manufactured easily with low cost.

In addition, since the SiGe film 10 is a thin film having favorable film-thickness uniformity, local defective processing such as the dent of the silicon substrate 2 caused by voids in the SiGe film during dry etching for forming the gate electrode can be avoided. Thereby, the process margin in the gate processing can be enlarged, and high-performance transistors can be stably manufactured.

### Second Embodiment

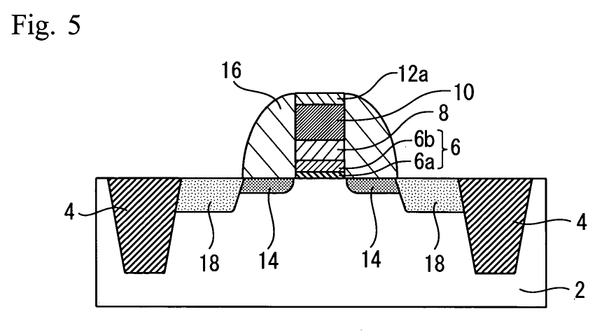

FIG. 5 is a schematic cross-sectional view for illustrating a semiconductor device according to a second embodiment of the present invention.

The semiconductor device according to the second embodiment shown in FIG. 5 differs from the above-described semiconductor device according to the first embodiment in that the upper cap Si film 12b and the silicide layers 20 are not formed. Other structure is the same as the first embodiment.

Next, a method for manufacturing the semiconductor device will be described.

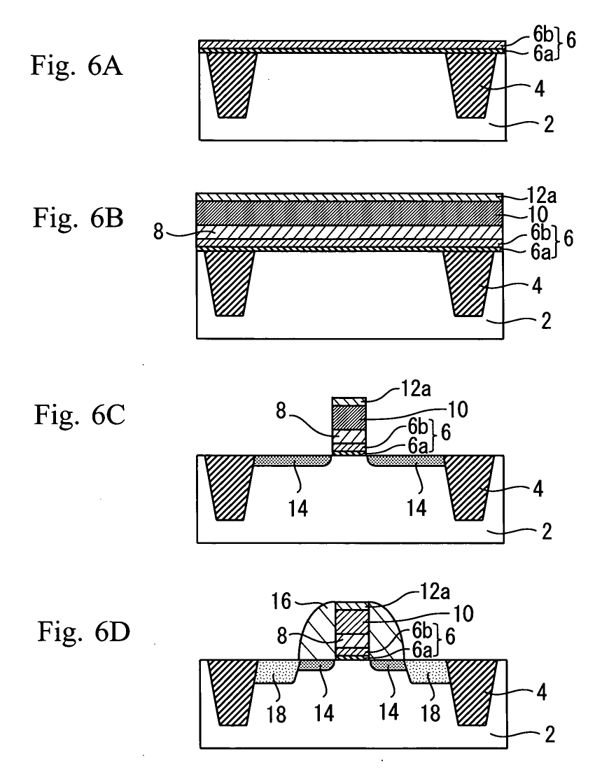

FIGS. 6A to 6D are process sectional views for illustrating a method for manufacturing the semiconductor device according to the second embodiment.

First, in the same manner as in the manufacturing method according to the first embodiment, elements up to the high-k dielectric film 6b are formed. Thus, the structure shown in FIG. 6A is attained.

As described in the first embodiment, after formation of the high-k dielectric film 6b, thermal process (annealing) can be performed in atmosphere including a little oxygen. Furthermore, a thin silicon nitride (SiN film) or a thin aluminum nitride (AlN film) with a thickness of 0.1 nm to 1 nm can be formed on the high-k dielectric film 6b.

Next, in the same manner as in the manufacturing method according to the first embodiment, an amorphous Si film serving as a seed Si film 8 is formed on the high-k dielectric film 6b. As described in the first embodiment, in order to attain the maximum improvement of electrical characteristic of the SiGe film 10, a thickness of the seed Si film 8 is preferably 0.1 nm or more and smaller than 5 nm, and more preferably 1 nm to 3 nm. Then, in the same manner as in the manufacturing method according to the first embodiment, a SiGe film 10 is formed on the seed Si film 8, and a lower cap film 12a having the same form as the SiGe film 10 with a thickness of about 5 nm is formed at the same growth temperature as the SiGe film 10. Thus, the structure shown in FIG. 6B is attained.

Next, after conductive impurities are introduced in the cap Si film 12a and the SiGe film 10, the cap Si film 12a, the SiGe film 10, the seed Si film 8, and the gate dielectric film 6 are sequentially patterned using lithography technique and etching technique well known in the art. Thereby, as FIG. 6C shows, the gate electrode of the MOSFET is formed.

Conductive impurities are implanted in the silicon substrate 2 using a patterned gate electrode and gate dielectric film 6 as a mask, and thermal process is performed. Thereby, extension regions 14 are formed in the upper portion of the substrate 2.

Next, an insulating film such as Si₃N₄ or SiO₂ is formed over the entire of the silicon substrate 2, and the insulating film is etched using an anisotropic dry etching method. Thus, as FIG. 6D shows, sidewall-spacers 16 are formed on the sides of the gate electrode and the gate dielectric film 6.

Conductive impurities are implanted in the silicon substrate 2 using the gate electrode, the gate dielectric film 6 and the sidewall-spacers 16 as a mask, and thermal process is performed. Thereby, source-drain regions 18 connected to the extension regions 14 are formed in the upper portion of the substrate 2.

In the second embodiment, as described above, the SiGe film 10 is formed on the high-k dielectric film 6b through the seed Si film 8 of a thickness of 0.5 nm to 5 nm. Therefore, the same effects as attained in the first embodiment can be attained.

### Third Embodiment

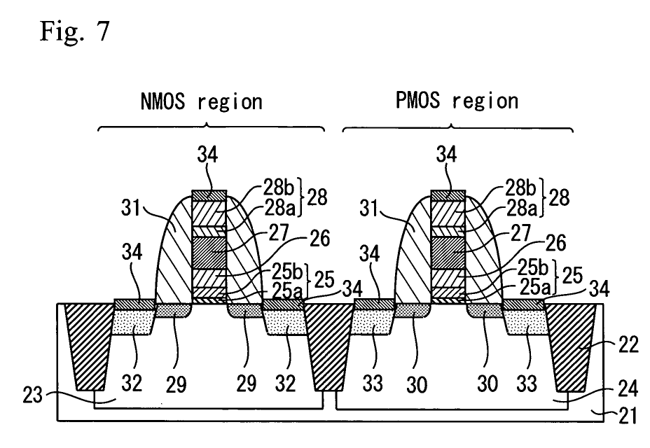

FIG. 7 is a schematic cross-sectional view for illustrating a semiconductor device according to a third embodiment of the present invention. Specifically, FIG. 7 is a schematic cross-sectional view for illustrating a CMOS (complementary metal oxide semiconductor) application.

As FIG. 7 shows, field insulating films 22 are formed in a silicon substrate 21. NMOS (n-channel MOS) regions and PMOS (p-channel MOS) regions are isolated by the field insulating films 22. P-well regions 23 are formed in the silicon substrate 21 of the NMOS regions, and n-well regions 24 are formed in the silicon substrate 21 of the PMOS regions.

On the p-well regions 23 and n-well regions 24, a gate dielectric film 25 laminated an underlying interfacial layer 25a and a high-k dielectric film 25b is formed in the same way as the first embodiment.

On the gate dielectric film 25 is formed a gate electrode composed of the laminate of a seed Si film 26, a SiGe film 27, a lower cap Si film 28a, an upper cap Si film 28b and a silicide layer 34.

Sidewalls 31 are formed on the sides of the gate dielectric film 25, the seed Si film 26, the SiGe film 27 and the cap film 28.

In NMOS regions, n-type extension regions 29 sandwiching a channel region (not shown) underneath the gate electrode are formed in the upper layer of the silicon substrate 21, and n-type source-drain regions 32 connecting to the n-type extension regions 29 are formed in the upper layer of the silicon substrate 21.

In PMOS regions, p-type extension regions 30 sandwiching a channel region (not shown) underneath the gate electrode are formed in the upper layer of the silicon substrate 21, and p-type source-drain regions 33 connecting to the p-type extension regions 30 are formed in the upper layer of the silicon substrate 21.

Nickel silicide layers serving as silicide layers 34 are formed in upper layers of the upper cap Si film 28b and the source-drain regions 32,33. That is to say, CMOSFET of the third embodiment has salicide structures.

Next, a method for manufacturing the semiconductor device will be described.

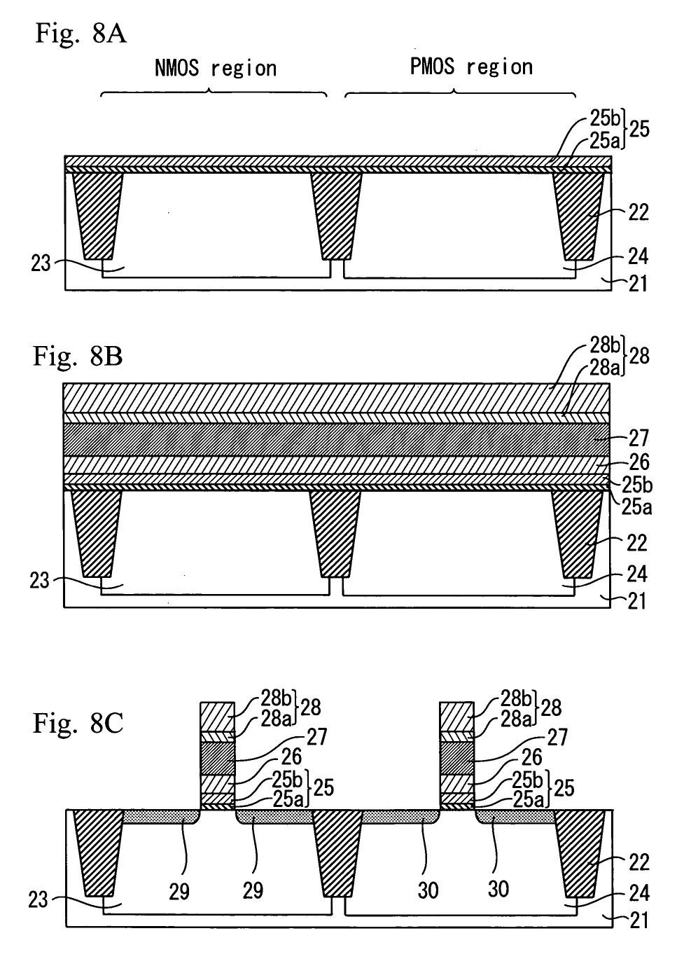

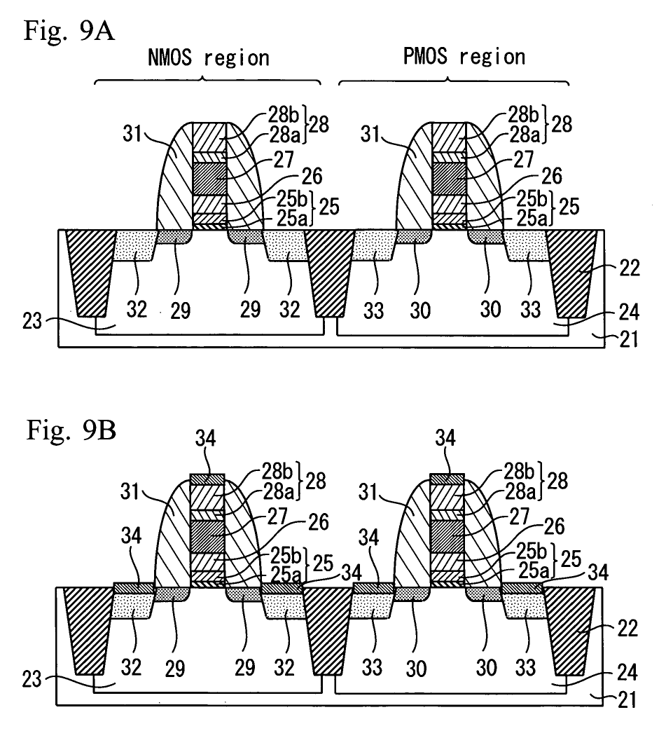

FIGS. 8A to 9B are process sectional views for illustrating a method for manufacturing the semiconductor device shown in FIG. 7.

First, as FIG. 8A shows, field insulating films 22 are formed using STI (shallow trench isolation) technique in isolation regions. P-type conductive impurities are implanted in active regions of NMOS regions, and thermal process is performed, thereby forming p-type well regions. N-type conductive impurities are implanted in active regions of PMOS regions, and thermal process is performed, thereby forming n-type well regions.

Next, after a predetermined pretreatment (e.g., the removal of natural oxide films) has been performed, a SiO₂ film or the like (described above) with a thickness of, for example, 0.5 nm to 1 nm is formed as an underlying interfacial layer 25a on the silicon substrate 21 using a method such as thermal oxidation (or thermal nitriding or thermal oxynitriding) or plasma oxidation (or plasma nitriding or plasma oxynitriding).

Next, a high-k dielectric film 25b having higher dielectric constant than the underlying interfacial layer 25a is formed on the underlying interfacial layer 25a using an ALD (atomic layer deposition) method or an MOCVD (metal organic chemical vapor deposition) method. For example, when the HfAlOx film is formed as the high-k dielectric film 25b using ALD method, the following process conditions can be used, raw material: HfCl₄ and TMA (trimethyl-aluminum); oxidizer: H₂O or O₃; and substrate temperature: 300° C.

Thus, the gate dielectric film 25 laminated the underlying interfacial layer 25a and the high-k dielectric film 25b is formed in the silicon substrate 21.

As described in the first embodiment, after formation of the high-k dielectric film 25b, thermal process (annealing) can be performed in atmosphere including a little oxygen. Furthermore, a thin silicon nitride (SiN film) or a thin aluminum nitride (AlN film) with a thickness of 0.1 nm to 1 nm can be formed on the high-k dielectric film 25b.

Next, in the same manner as in the manufacturing method according to the first embodiment, an amorphous Si film serving as a seed Si film 26 is formed on the high-k dielectric film 25b. As described in the first embodiment, in order to attain the maximum improvement of electrical characteristic of the SiGe film 27, a thickness of the seed Si film 26 is preferably 0.1 nm or more and smaller than 5 nm, and more preferably 1 nm to 3 nm. Then, in the same manner as in the manufacturing method according to the first embodiment, a SiGe film 27 is formed on the seed Si film 26, and the cap film 28a having the same form as the SiGe film 27 with a thickness of about 5 nm is formed at the same growth temperature as the SiGe film 27. Thereafter, the upper cap Si film 28b is formed at the higher temperature than the lower cap Si film 28a. Thus, the structure shown in FIG. 8B is attained.

Next, conductive impurities are introduced in the cap Si film 28 and the SiGe film 27. Then, the cap Si film 28, the SiGe film 27, the seed Si film 26, and the gate dielectric film 25 are sequentially patterned using lithography technique and etching technique well known in the art. Thereby, as FIG. 8C shows, the gate electrode of the CMOSFET is formed. Next, n-type conductive impurities such as As ions are implanted in the low concentration in the silicon substrate 21 of the NMOS regions using a patterned gate electrode as a mask, and thermal process is performed, and thereby forming n-type extension regions 29 in the upper portion of the substrate 21. P-type conductive impurities such as Boron ions are implanted in the low concentration in the silicon substrate 21 of the PMOS regions using a patterned gate electrode as a mask, and thermal process is performed, and thereby forming p-type extension regions 30 in the upper portion of the substrate 21.

Next, an insulating film such as Si₃N₄ or SiO₂ is formed over the entire of the silicon substrate, and the insulating film is etched using an anisotropic dry etching method. Thus, as FIG. 9A shows, sidewall-spacers 31 are formed on the sides of the gate electrode and the gate dielectric film 25.

N-type conductive impurities such as As ions are implanted in the high concentration in the silicon substrate 21 of the NMOS regions using gate electrode and the sidewall-spacers 31 as a mask, and thermal process is performed. Thereby, n-type source-drain regions 32 connected to the n-type extension regions 29 are formed in the upper portion of the substrate 21.

P-type conductive impurities such as Boron ions are implanted in the high concentration in the silicon substrate 21 of the PMOS regions using gate electrode and the sidewall-spacers 31 as a mask, and thermal process is performed. Thereby, p-type source-drain regions 33 connected to the p-type extension regions 30 are formed in the upper portion of the substrate 21.

Next, as FIG. 9B shows, silicide layers 34 are formed in upper portions of the upper cap Si film 28b and the source-drain regions 32,33 using self-aligned silicide formation technique called “salicide technique”.

Specifically, after a predetermined pretreatment has been performed using diluted HF solution, a Ni film with thickness of about 10 nm is formed over the entire of the silicon substrate 21, and a TiN film with thickness of about 10 nm is formed on the Ni film. Thereafter, a heat treatment with a temperature of about 500° C. and time of about 30 seconds is performed. Thus, Ni film is reacted with the upper cap Si film 28b and the source-drain regions 32,33, and no-reacted metal is removed. Thereby, NiSi layers serving as the silicide layers 34 are formed.

In the third embodiment, as described above, the SiGe film 10 is formed through the seed Si film 8 of a thickness of 0.5 nm to 5 nm on the high-k dielectric film 6b formed in the NMOS regions and the PMOS regions. Therefore, the same effects as attained in the first embodiment can be attained.

In the same way as the second embodiment, the formation of the upper cap Si film 28b and the NiSi layers 34 can be omitted.

This invention, when practiced illustratively in the manner described above, provides the following major effects:

According to the present invention, a void-free SiGe film having good surface flatness can be formed on a high-k dielectric film. Further, high-quality continuous films including the SiGe film and the cap Si film can be formed on the high-k dielectric film.

Further, the present invention is not limited to these embodiments, but variations and modifications may be made without departing from the scope of the present invention.

The entire disclosure of Japanese Patent Application No. 2003-307148 filed on Aug. 29, 2003 containing specification, claims, drawings and summary are incorporated herein by reference in its entirety.

1-13. (canceled)

14. A method for manufacturing a semiconductor device, comprising:
forming a high-k dielectric film as a gate dielectric film on a substrate;
forming a seed Si film on the high-k dielectric film;
forming a SiGe film on the seed Si film; and
patterning the SiGe film and the seed Si film to form a gate electrode, and patterning the high-k dielectric film; and
forming doped regions in an upper region of the substrate by ion implantation, using the gate electrode as a mask.

15. The method for manufacturing a semiconductor device according to claim 14, further comprising:
forming a lower cap Si film continuously with the SiGe film at the same temperature as forming of the SiGe film, on the SiGe film, after formation of the SiGe film;
forming an upper cap Si film on the lower cap Si film at a temperature higher than the temperature of forming the SiGe film, wherein the upper cap Si film, the lower cap Si film, the SiGe film, and the seed Si film are patterned to form the gate electrode, and
forming silicide layers as upper layers of the upper cap Si film and the doped regions, after formation of the doped regions.

16. The method for manufacturing a semiconductor device according to claim 15, including forming the upper cap Si film at a temperature of at least 530° C. and no higher than 650° C.

17. The method for manufacturing a semiconductor device according to claim 14, including forming the SiGe film at a temperature of at least 450° C. and less than 500° C.

18. The method for manufacturing a semiconductor device according to claim 14, including forming the seed Si film to a thickness of at least 0.1 nm and smaller than 5 nm.

19. A method for manufacturing a semiconductor device, comprising:
forming a laminated gate dielectric film including an underlying interfacial layer and a high-k dielectric film, having a higher dielectric constant than the underlying interfacial layer, on a substrate;
forming a seed Si film with a thickness of at least 0.1 nm and smaller than 5 nm on the high-k dielectric film;
forming a SiGe film at a temperature of at least 450° C. and less than 500° C. on the seed Si film
forming a lower cap Si film at the same temperature as forming of the SiGe film, with a thickness of 0.5 at least nm and no more than 5 nm, on the SiGe film;
forming an upper cap Si film on the lower cap Si film at a temperature higher than the temperature of forming the lower SiGe film;
patterning the upper cap Si film, the lower cap Si film, the SiGe film, and the seed Si film to form a gate electrode, and patterning the high-k dielectric film and the underlying interfacial layer;
forming extension regions in an upper region of the substrate by ion implantation, using the gate electrode as a mask and performing a thermal process;
forming sidewalls covering sides of the gate electrode;
forming source-drain regions in an upper region of the substrate by ion implantation, using the sidewalls and gate electrode as a mask, and performing a thermal process; and
forming silicide layers in upper portions of the upper cap Si film and the source-drain regions by saliciding.

20. A method for manufacturing a semiconductor device including n-type circuit regions and p-type circuit regions, the method comprising:
forming p-type well regions in an upper region of a substrate of the n-type circuit regions, and forming n-type well regions in an upper region of the substrate of the p-type circuit regions;
forming a laminated gate dielectric film, including an underlying interfacial layer and a high-k dielectric film, having a higher dielectric constant than the underlying interfacial layer, on the p-type well regions and the n-type well regions;
forming a seed Si film with a thickness of at least 0.1 nm and smaller than 5 nm on the high-k dielectric film;
forming a SiGe film at a temperature of at least 450° C. and less than 500° C. on the seed Si film
forming a lower cap Si film at the same temperature as forming of the SiGe film, with a thickness of at least 0.5 nm and no more than 5 nm, on the SiGe film;
forming an upper cap Si film on the lower cap Si film at a temperature higher than the temperature of forming the lower SiGe film;
patterning the upper cap Si film, the lower cap Si film, the SiGe film, and the seed Si film to form a gate electrode, and patterning the high-k dielectric film and the underlying interfacial layer;
forming n-type extension regions in an upper region of the p-type well regions by ion implantation of n-type impurities using the gate electrode as a mask and performing a thermal process;
forming p-type extension regions in upper layer of the p-type well regions by ion implantation of p-type impurities using the gate electrode as a mask and performing a thermal process;
forming sidewalls covering sides of the gate electrode;
forming n-type source-drain regions in an upper region of the p-type well regions through ion implantation of n-type impurities using the sidewalls and gate electrode as a mask and performing a thermal process;
forming p-type source-drain regions in an upper region of the p-type well regions by ion implantation of p-type impurities using the sidewalls and gate electrode as a mask and performing a thermal process; and
forming silicide layers in upper portions of the upper cap Si film and the source-drain regions by saliciding.
